(19) United States
(12) Patent Application Publication
(10) Pub. No.: US 2021/0232794 A1
(43) Pub. Date: Jul. 29, 2021

(54) ELECTRONIC DEVICE

(71) Applicant: InnoLux Corporation, Miao-Li-County (TW)

(72) Inventors: CHANDRA LIUS, Miao-Li County (TW); Kuan-Feng Lee, Miao-Li County (TW); Yu-Chia Huang, Miao-Li County (TW); Hsiao-Lan Huang, Miao-Li County (TW)

(21) Appl. No.: 17/121,786

(22) Filed: Dec. 15, 2020

(30) Foreign Application Priority Data
Jan. 23, 2020 (CN) 202010076476.9

(51) Int. Cl. G06K 9/00; G06F 3/041; H01L 31/0232; F21V 8/00; H01L 31/14

(52) U.S. Cl. CPC G06K 9/0004; G06F 3/0412; H01L 31/143; G02B 6/0088; H01L 31/02327

(57) ABSTRACT

An electronic device is disclosed in the present disclosure. The electronic device comprises a substrate, a first layer and a second layer. The first layer is disposed on the substrate, and the second layer is disposed on the substrate and surrounds the first layer. An interface between the first layer and the second layer forms a light guiding channel, thereby improving the intensity of a light received by an optical sensor.

### BACKGROUND OF THE DISCLOSURE

### 1. Field of the Disclosure

The present disclosure relates to an electronic device, more particularly to an electronic device having light guiding channel.

### 2. Description of the Prior Art

Electronic devices have become an indispensable tool in people's lives. Some of the electronic devices are equipped with the optical sensor to detect fingerprint images. However, the problem of poor fingerprint images detected by the optical sensor still remains to be resolved.

### SUMMARY OF THE DISCLOSURE

According to an embodiment of the present disclosure, an electronic device is provided. The electronic device comprises a substrate, a first layer and a second layer. The first layer is disposed on the substrate, and the second layer is disposed on the substrate and surrounds the first layer. An interface between the first layer and the second layer forms a light guiding channel.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 schematically illustrates a cross-sectional view of an electronic device according to the first embodiment of the present disclosure.

FIG. 2A schematically illustrates a cross-sectional view of an electronic device according to the second embodiment of the present disclosure.

FIG. 2B schematically illustrates a cross-sectional view of an electronic device according to a variant embodiment of the second embodiment of the present disclosure.

FIG. 3A schematically illustrates a cross-sectional view of an electronic device according to the third embodiment of the present disclosure.

FIG. 3B schematically illustrates a cross-sectional view of an electronic device according to a variant embodiment of the third embodiment of the present disclosure.

FIG. 4 schematically illustrates a cross-sectional view of an electronic device according to the fourth embodiment of the present disclosure.

FIG. 5A schematically illustrates a cross-sectional view of an electronic device according to the fifth embodiment of the present disclosure.

FIG. 5B schematically illustrates a cross-sectional view of an electronic device according to a variant embodiment of the fifth embodiment of the present disclosure.

FIG. 6 schematically illustrates a cross-sectional view of an electronic device according to the sixth embodiment of the present disclosure.

### DETAILED DESCRIPTION

The present disclosure may be understood by reference to the following detailed description, taken in conjunction with the drawings as described below, and for purposes of illustrative clarity and being easily understood by the readers, various drawings of this disclosure may be simplified, and the elements in various drawings may not be drawn to scale. In addition, the number and dimension of each element shown in drawings are only illustrative and are not intended to limit the scope of the present disclosure.

Certain terms are used throughout the description and following claims to refer to particular elements. As one skilled in the art will understand, electronic equipment manufacturers may refer to an element by different names. This document does not intend to distinguish between elements that differ in name but not function. In the following description and in the claims, the terms “comprise”, “include” and “have” are used in an open-ended fashion, and thus should be interpreted to mean “include, but not limited to . . . ”.

The direction terms used in the following embodiment such as up, down, left, right, in front of or behind are only the directions referring to the attached figures. Thus, the direction terms used in the present disclosure are for illustration, and are not intended to limit the scope of the present disclosure. It should be noted that the elements which are specifically described or labeled may exist in various forms for those skilled in the art. Besides, when a layer is referred to as being “on” another element or layer, or is referred to as being “connected” to another element or layer, it may be directly on or connected to the other element or layer, or intervening layers or elements may be included between the layer and the other element or layer (indirectly). In contrast, when an element or layer is referred to as being “directly on” or “directly connected to” another element or layer, there are no intervening elements or layers present. In addition, the word “electrically connected” may include any direct or indirect electrical connection means.

The ordinal numbers such as “first”, “second”, etc. are used in the specification and claims to modify the elements in the claims. It does not mean that the required element has any previous ordinal number, and it does not represent the order of a required element and another required element or the order in the manufacturing method. The ordinal number is only used to distinguish the required element with a certain name and another required element with the same certain name.

It should be noted that the technical features in different embodiments described in the following may be replaced, recombined, or mixed with one another to constitute another embodiment without departing from the spirit of the present disclosure.

The electronic device of the present disclosure may include display device, antenna device, light emitting device, sensing device or tiled device, but not limited thereto. The electronic device may include foldable electronic device or flexible electronic device. The antenna device may for example be a liquid crystal antenna, but not limited thereto. The tiled device may for example include tiled display device or tiled antenna device, but not limited thereto. It should be noted that the electronic device may be the combinations of the above-mentioned electronic devices, but not limited thereto.

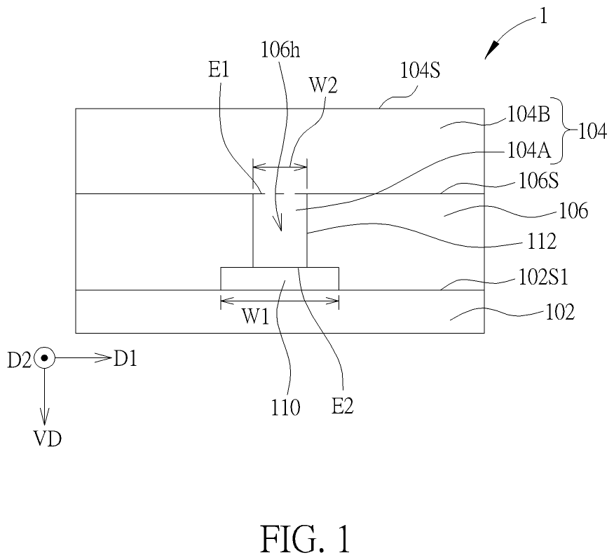

FIG. 1 schematically illustrates a cross-sectional view of an electronic device according to a first embodiment of the present disclosure. For clarity, the structure of the light guiding channel is shown in FIG. 1, and the other elements are omitted, but not limited thereto. As shown in FIG. 1, the electronic device 1 may include a substrate 102, a first layer 104 and a second layer 106. In a cross section parallel to the normal direction VD of the substrate 102, the first layer 104 is disposed on the substrate 102, the second layer 106 is disposed on the substrate 102 and surrounds the first layer 104, and an interface (such as interface 112) between the first layer 104 and the second layer 106 may form a light guiding channel 104A. In an embodiment, the refractive index of the first layer 104 may be greater than the refractive index of the second layer 106, the second layer 106 may include a hole 106h, and the first layer 104 may at least be disposed in the hole 106h such that the first layer 104 located in the hole 106h may be surrounded by the second layer 106 and in contact with the second layer 106 to form the interface 112, thereby forming the light guiding channel 104A. In the present disclosure, the light guiding channel 104A may be defined as the portion of the first layer 104 surrounded by the second layer 106, for example, the first layer 104 located in the hole 106h, but not limited thereto. The interface 112 of the present embodiment shown in FIG. 1 may be located at a sidewall of the hole 106h, but not limited thereto. The light guiding channel 104A of the first layer 104 may be a portion of the first layer 104 surrounded by the interface 112. Because the refractive index of the light guiding channel 104A in the hole 106h may be greater than the refractive index of the second layer 106, such that the total reflection of the light in the light guiding channel 104A may easily occur at the interface 112, the portion of the first layer 104 surrounded by the interface 112 may be regarded as the light guiding channel 104A. When the light is transmitted from an edge E1 of the light guiding channel 104A to another edge E2 of the light guiding channel 104A, the situation of decay of the intensity of the light may be mitigated. In some embodiments, the first layer 104 may further include a film portion 104B disposed on a top surface 106S of the second layer 106. The extending direction of the light guiding channel 104A may for example be substantially parallel to the normal direction VD of the substrate 102, but not limited thereto. In some embodiments, the extending direction of the light guiding channel 104A and the normal direction VD of the substrate 102 may include an included angle, and the included angle may be greater than 0 degree and less than 90 degrees, but not limited thereto. In some embodiments, the shape of the hole 106h in a cross section perpendicular to the normal direction VD may for example be a circle, a rectangle, an oval, an irregular shape or other suitable shapes, but not limited thereto. In some embodiments, the shape of the hole 106h in a cross section parallel to the normal direction VD may for example be a rectangular, a trapezoid in which the upper side is wider than the lower side, an irregular shape or other suitable shapes, but not limited thereto. In some embodiments, the shape of the sidewall of the hole 106h in a cross section parallel to the normal direction VD may for example be a line, an arc, a curved line or other suitable shapes, but not limited thereto. In some embodiments, the light in the light guiding channel 104A may for example be the light entering from the outside of a top surface 104S of the film portion 104B or the light reflected by the top surface 104S in the film portion 104B, but not limited thereto.

In an embodiment, the electronic device 1 may further include an optical sensor 110 disposed at the edge E2 of the light guiding channel 104A, and the optical sensor 110 may at least partially overlap the light guiding channel 104A in the normal direction VD of the substrate 102, such that the optical sensor 110 may receive the light guided by the light guiding channel 104A. For example, the optical sensor 110 may have a maximum width, and the maximum width of the optical sensor 110 may be greater than or equal to the maximum width of the bottom of the hole 106h. In an embodiment, the maximum width W1 of the optical sensor 110 along a direction perpendicular to the normal direction VD may be greater than or equal to the maximum width W2 of the bottom of the hole 106h along the direction perpendicular to the normal direction VD, and the optical sensor 110 may be disposed between the hole 106h of the second layer 106 and the substrate 102. The direction perpendicular to the normal direction VD may for example be the direction D1, the direction D2 or other directions parallel to the plane formed by the direction D1 and the direction D2, but not limited thereto. In the embodiment shown in FIG. 1, the hole 106h may be a through hole, and therefore, the second layer 106 is not disposed between the light guiding channel 104A and the optical sensor 110, and the optical sensor 110 may be directly in contact with the edge E2 of the light guiding channel 104A, such that the light guided through the light guiding channel 104A would be directly emitted on the optical sensor 110 without passing through the second layer 106 to reduce loss of the intensity of the light. In some embodiments, the hole 106h may be a blind hole, and a portion of the second layer 106 may be disposed between the light guiding channel 104A and the optical sensor 110. In some embodiments, when the optical sensor 110 is disposed between the edge E2 of the light guiding channel 104A and the substrate 102, other layers may exist between the optical sensor 110 and the edge E2 of the light guiding channel 104A. In some embodiments, the substrate 102 may be disposed between the optical sensor 110 and the edge E2 of the light guiding channel 104A. The optical sensor 110 may for example include photodiode sensor or other suitable sensors.

It should be noted that when the electronic device 1 includes a plurality of optical sensors 110, the plurality of optical sensors 110 may detect the light reflected by the object to detect the image of the object. The image of the object may for example be the image of fingerprint or other objects that need to be detected, but not limited thereto. The light guiding channel 104A may reduce the loss of the intensity of the light passing through the light guiding channel 104A, thereby increasing the sharpness of the image of the object detected by the optical sensor 110.

The substrate 102 may for example include rigid substrate or flexible substrate. The rigid substrate may for example include glass, ceramic, quartz, sapphire or other suitable materials, but not limited thereto. The flexible substrate may for example include polyimide (PI), polyethylene terephthalate (PET), polycarbonate (PC), polyethersulfone (PES), polybutylene terephthalate (PBT), polyethylene naphthalate (PEN), polyarylate (PAR), other suitable materials or the combinations of the above-mentioned materials, but not limited thereto. In the situation that the refractive index of the first layer 104 is greater than the refractive index of the second layer 106, the first layer 104 and the second layer 106 may for example include inorganic materials, acrylic-based organic materials, silicon-based organic materials, other suitable organic materials or the combinations of the above-mentioned materials, but not limited thereto. The inorganic material may for example include silicon oxide, silicon nitride, the combination of the above-mentioned materials or other suitable materials, but not limited thereto. The acrylic-based materials may for example be poly(methyl methacrylate) (PMMA), other suitable materials or the combination of the above-mentioned materials. For example, the first layer 104 may include organic material, and the second layer 106 may include inorganic material. For example, when the first layer 104 is formed of acrylic-based materials and has the refractive index of 1.54 for light having the wavelength of 550 nanometers (nm), the second layer 106 may be formed of silicon oxide, and therefore, the second layer may have a refractive index of 1.51 for light having the wavelength of 550 nanometers, and the refractive index of the second layer 106 is less than the refractive index of the first layer 104.

In an embodiment, the first layer 104 may be a single-layer structure, and the second layer 106 may be a single-layer structure, but not limited thereto. In some embodiments, the first layer 104 may be a multi-layer structure, and the layers in the multi-layer structure may be arranged in sequence along the direction from the center of the hole 106h toward the sidewall of the hole 106h. In some embodiments, the second layer 106 may be a multi-layer structure in which the layers are stacked in sequence on the substrate 102. In some embodiments, when the second layer 106 is a multi-layer structure, the first layer 104 may be a single-layer structure.

The electronic device of the present disclosure is not limited to the above-mentioned embodiment and may include different embodiments or variant embodiments. In order to simplify the description, the elements of different embodiments and variant embodiments and the same element of the first embodiment will use the same label. In order to clearly describe different embodiments and variant embodiments, the following contents would focus on the difference between the first embodiment and different embodiments or variant embodiments, and the repeated portion will not be redundantly described.

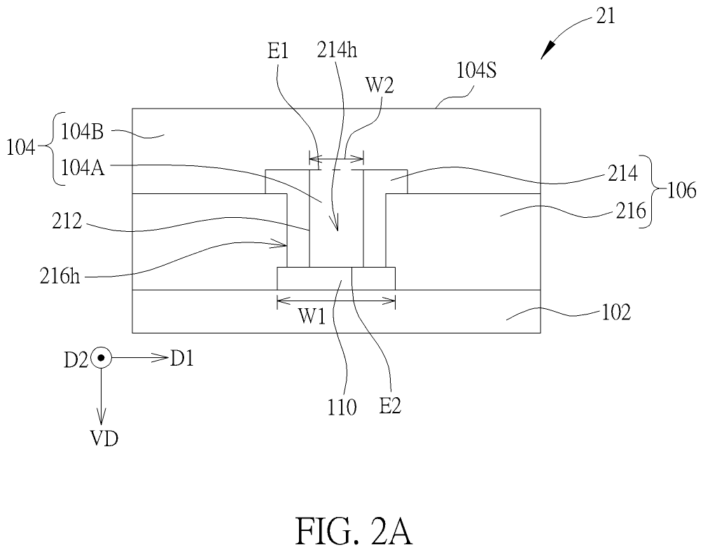

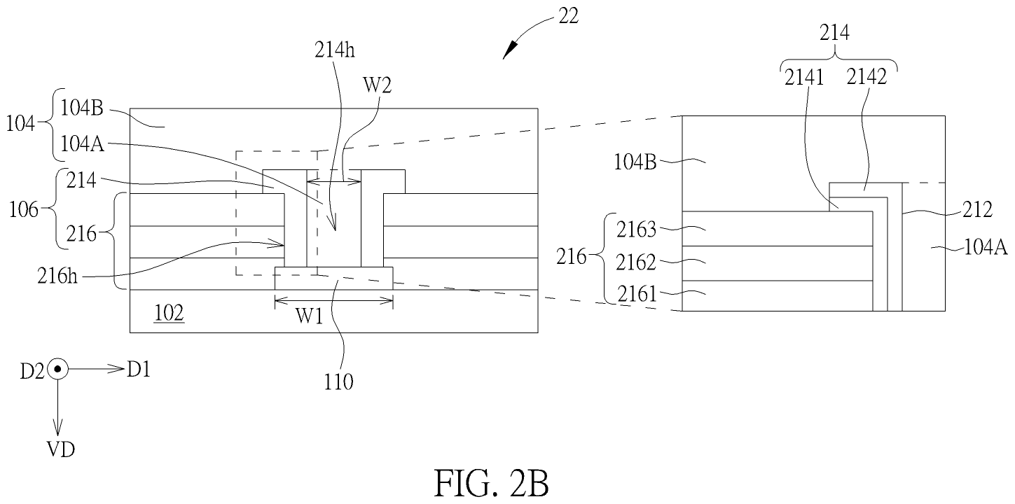

FIG. 2A schematically illustrates a cross-sectional view of an electronic device according to a second embodiment of the present disclosure. For clarity, the structure of the light guiding channel is shown in FIG. 2A, and the other elements are omitted, but not limited thereto. As shown in FIG. 2A, the difference between the electronic device 21 in the second embodiment and the electronic device 1 shown in FIG. 1 is that the second layer 106 may include a reflector 214 to form the light guiding channel 104A in the present embodiment. In an embodiment, the second layer 106 may further include a layer 216 having a hole 216h, and the reflector 214 may be disposed on a sidewall of the hole 216h. The reflector 214 includes another through hole 214h, and the first layer 104 may at least be disposed in the through hole 214h to form the light guiding channel 104A. In other words, the reflector 214 having reflective characteristic may surround the first layer 104 located in the through hole 214h, so an interface 212 may be formed between the reflector 214 and the surface of the first layer 104 in the through hole 214h, and the light guiding channel 104A may be formed. The interface 212 of the present embodiment shown in FIG. 2A may be located at a sidewall of the through hole 214h, and the light guiding channel 104A may be formed of a portion of the first layer 104 surrounded by the sidewall of the through hole 214h, but not limited thereto. In some embodiments, the hole 216h of the layer 216 may be a through hole or a blind hole. In some embodiments, the light guiding channel 104A may overlap the optical sensor 110 in the normal direction VD of the substrate 102. In some embodiments, a portion of the reflector 214 may extend to be on a surface of the layer 216 outside the hole 216h. The reflector 214 may for example include materials with high reflectivity, but not limited thereto. The materials with high reflectivity may include metal (such as aluminum), but not limited thereto. In some embodiments, the reflector 214 may be a single-layer structure or a multi-layer structure. In some embodiments, the minimum thickness of the reflector 214 along the direction perpendicular to the normal direction VD may be greater than or equal to 0.2 micrometers (μm). In some embodiments, the layer 216 may be a single-layer structure or a multi-layer structure.

FIG. 2B schematically illustrates a cross-sectional view of an electronic device according to a variant embodiment of the second embodiment of the present disclosure. For clarity, the structure of the light guiding channel is shown in FIG. 2B, and the other elements are omitted, but not limited thereto. As shown in FIG. 2B, the difference between the electronic device 22 of the present variant embodiment and the electronic device 21 shown in FIG. 2A is that the reflector 214 includes multiple layers, and the multiple layers have at least two different refractive indices in the present variant embodiment. Through the stacking of layers with different refractive indices, total reflection may occur in the multiple layers, and the interface 212 may be formed between the multiple layers and the light guiding channel 104A. In some embodiments, each of the layers may have different refractive indices. Specifically, in an embodiment, the multiple layers may include at least one high refractive index layer 2142 and at least one low refractive index layer 2141, the low refractive index layer 2141 is disposed between the sidewall of the hole 216h of the layer 216 and the high refractive index layer 2142, and the refractive index of the high refractive index layer 2142 is greater than the refractive index of the low refractive index layer 2141. For example, the multiple layers may include two high refractive index layers 2142 and a low refractive index layer 2141, and the high refractive index layer 2142, the low refractive index layer 2141 and the high refractive index layer 2142 are alternately stacked on the sidewall of the hole 216h along the direction from the interface 212 toward the sidewall of the hole 216h. Alternatively, the multiple layers may include a plurality of high refractive index layers 2142 and a plurality of low refractive index layers 2141, and the high refractive index layer 2142, the low refractive index layer 2141 and the high refractive index layer 2142 may be alternately stacked in sequence. In other words, the reflector 214 may for example be a Bragg reflector. In some embodiments, the high refractive index layer 2142 may for example include silicon nitride (SiNx), hydrogenated silicon nitride (SiNx:H), titaniumoxide (TiO₂), trititaniumpentoxide (Ti₃O₅), titanium sesquioxide (Ti₂O₃), titanium monoxide (TiO), tantalum pentoxide (Ta₂O₅), zirconium oxide (ZrO₂), niobium oxide (Nb₂O₅), zinc oxide (ZnO), yttrium oxide (Y₂O₃) or cerium oxide (CeO₂), and the low refractive index layer 2141 may for example include silicon dioxide (SiO₂), hydrogenated silicon nitride, silicon monoxide (SiO) or aluminum oxide (Al₂O₃), but the present disclosure is not limited thereto. In some embodiments, the number of the high refractive index layers 2142 and the number of the low refractive index layers 2141 may be the same or different. In some embodiments, the thickness of the high refractive index layer 2142 and the thickness of the low refractive index layer 2141 may be the same or different. In some embodiments, the high refractive index layer 2142 and the low refractive index layer 2141 may extend to be on the layer 216 outside the hole 216h.

In some embodiments, the second layer 106 may be a multi-layer structure. Specifically, the layer 216 of the second layer 106 may be a multi-layer structure and may include a plurality of sub layers. For example, the plurality of sub layers may include a first sub layer 2161, a second sub layer 2162 and a third sub layer 2163 stacked on the substrate 102 in sequence, but not limited thereto. In such situation, at least two of the sub layers may include same material or different materials. When the second layer 106 is a multi-layer structure, the reflector 214 may be a single-layer structure or a multi-layer structure, and/or the first layer 104 may be a single-layer structure or a multi-layer structure.

For example, under the condition that the first layer 104 is formed of organic material and has a thickness of 1.5 micrometers, the second layer 106 is formed of silicon oxide, the depth of the hole 106h of the second layer 106 is 0.8 micrometers, and the width W1 of the optical sensor 110 is 20 micrometers, when the width W2 of the hole 106h of the electronic device 1 shown in FIG. 1 is 10 micrometers, the intensity of the light received by the optical sensor 110 shown in FIG. 1 through the light guiding channel 104A may be increased by 10% compared to the intensity of the light received by the optical sensor 110 in the case where the second layer 106 has no holes and no light guiding channels. Besides, under the same condition, the electronic device 21 shown in FIG. 2A is taken as an example, the width W2 of the hole 214h is 10 micrometers, and the reflector 214 is formed of aluminum with a thickness of 0.2 micrometers, the intensity of the light received by the optical sensor 110 shown in FIG. 2A through the light guiding channel 104A may be increased by 12% compared to the intensity of the light received by the optical sensor 110 in the case where the second layer 106 has no holes and no light guiding channel. Therefore, through the design of the light guiding channel 104A shown in FIG. 1 or the light guiding channel 104A shown in FIG. 2A or FIG. 2B, the intensity of the light received by the optical sensor 110 may be increased. When the optical sensor 110 is used for detection of the images of the objects, the design of the light guiding channel 104A may improve the sharpness of the detected images, such as the sharpness of the fingerprint images.

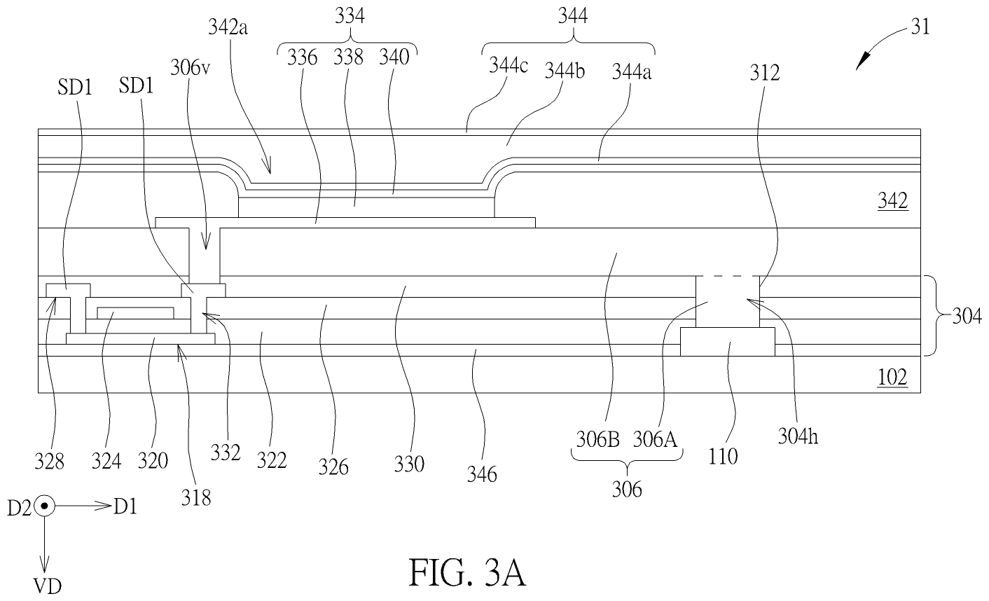

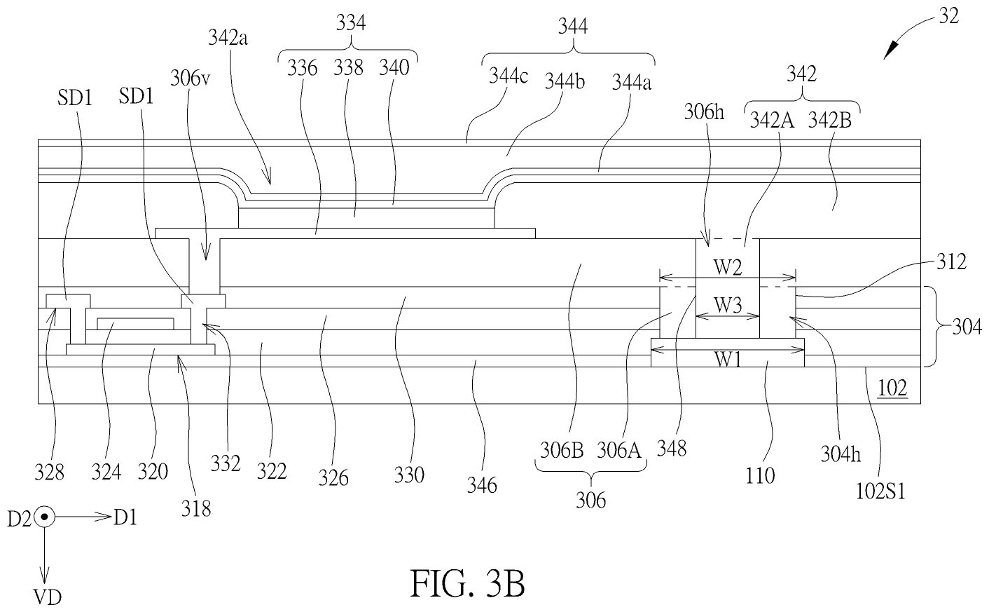

The embodiments of the exemplary application of the above-mentioned electronic device would be described in the following content, but the present disclosure is not limited to the below-mentioned embodiments. FIG. 3A schematically illustrates a cross-sectional view of an electronic device according to a third embodiment of the present disclosure. The electronic device 31 shown in FIG. 3A is for example a display device, but not limited thereto. As shown in FIG. 3A, the electronic device 31 may include a substrate 102, a circuit layer 304 and a planarization layer 306. In some embodiments, the substrate 102 may be a single-layer structure or a multi-layer structure. The circuit layer 304 is disposed on the substrate 102, the optical sensor 110 may be disposed on the substrate 102, and the circuit layer 304 may include a hole 304h located on the optical sensor 110. The planarization layer 306 may be disposed on the circuit layer 304, and a portion of the planarization layer 306 may be disposed in the hole 304h, such that the planarization layer 306 located on the optical sensor 110 and disposed in the hole 304h in the circuit layer 304 may form the light guiding channel 306A. For example, the planarization layer 306 may for example be similar to or the same as the first layer 104 shown in FIG. 1 or the first layer 104 shown in FIG. 2A or FIG. 2B, and the planarization layer 306 includes the light guiding channel 306A disposed in the hole 304h and the film portion 306B disposed on the circuit layer 304, but not limited thereto. In some embodiments, the circuit layer 304 may for example be a multi-layer structure, a portion of the circuit layer 304 may be similar to or the same as the second layer 106 shown in FIG. 1, and the hole 304h may be similar to or the same as the hole 106h shown in FIG. 1. In some embodiments, the circuit layer 304 may be similar to or the same as the layer 216 of the second layer 106 shown in FIG. 2B, or, the circuit layer 304 may further include the reflector 214 shown in FIG. 2A or FIG. 2B and disposed between the sidewall of the hole 304h and the light guiding channel 306A, but not limited thereto. In some embodiments, the circuit layer 304 may for example be a multi-layer structure, a portion of the multi-layer structure may form the switch element 318, and therefore, the switch element 318 may be embedded in the circuit layer 304. The switch element 318 may be used to control the display of the display device. The switch element 318 may for example include thin film transistor or other suitable transistor, but not limited thereto. In some embodiments, the circuit layer 304 may further include signal lines (not shown in FIGs) besides the switch element 318. The signal lines may for example include data lines, scan lines, common lines or other required signal lines.

In some embodiments, as shown in FIG. 3A, when the thin film transistor is the top-gate type transistor, the circuit layer 304 may include a semiconductor layer 320, an insulating layer 322, a conductive layer 324, an insulating layer 326, a conductive layer 328 and an insulating layer 330, but not limited thereto. In such situation, the semiconductor layer 320 may be disposed on the substrate 102 and include the channel layer of the thin film transistor; the insulating layer 322 may be disposed on the semiconductor layer 320 and the substrate 102 and include the gate insulating layer of the thin film transistor; the conductive layer 324 may be disposed on the insulating layer 322 and include the gate of the thin film transistor; the insulating layer 326 may be disposed on the conductive layer 324 and the insulating layer 322; the conductive layer 328 may be disposed on the insulating layer 326 and include the source/drains SD1 of the thin film transistor, and the source/drains SD1 may respectively be electrically connected to the semiconductor layer 320 through the through holes 332 of the insulating layer 326 and the insulating layer 322; and the insulating layer 330 may be disposed on the conductive layer 328 and the insulating layer 326. The insulating layer 322, the insulating layer 326 and the insulating layer 330 may extend onto the optical sensor 110, the insulating layer 322, the insulating layer 326 and the insulating layer 330 may include the hole 304h, and the refractive index of the insulating layer 322, the refractive index of the insulating layer 326 and the refractive index of the insulating layer 330 may be lower than the refractive index of the planarization layer 306, so that the stack of the insulating layer 322, the insulating layer 326 and the insulating layer 330 (similar to or the same as the second layer 106 shown in FIG. 1 or the layer 216 shown in FIG. 2A or FIG. 2B) and the planarization layer 306 in the hole 304h may form the interface 312, thereby forming the light guiding channel 306A by surrounding. In the embodiment shown in FIG. 3A the light guiding channel 306A may be formed of the portion of the planarization layer 306 surrounded by the hole 304h, but not limited thereto. The light guiding channel 306A may overlap the optical sensor 110 in the normal direction VD of the substrate 102. In some embodiments, the light guiding channel 306A in the hole 304h may directly be in contact with the optical sensor 110, but not limited thereto.

The conductive layer 324 and the conductive layer 328 may for example respectively include aluminum, molybdenum nitride, copper, titanium, other suitable materials or the combinations of the above-mentioned materials, but not limited thereto. The insulating layer 322, the insulating layer 326 and the insulating layer 330 may for example respectively include silicon oxide, silicon nitride, the combination of the above-mentioned materials or other suitable materials, but not limited thereto. At least two of the insulating layer 322, the insulating layer 326 and the insulating layer 330 may have the same refractive index or different refractive indices.

The type of the thin film transistor of the present disclosure is not limited to top-gate type which is shown in FIG. 3A. In some embodiments, the thin film transistor may for example be a bottom-gate type transistor, or a dual-gate type transistor or other suitable transistors according to the demands. Or, the thin film transistor may also include amorphous silicon transistor, low-temperature poly-silicon (LTPS) transistor or metal-oxide semiconductor (IGZO) transistor, but not limited thereto. With different types of the thin film transistor, the number of the insulating layers in the circuit layer 304 may be different, that is, the number of the insulating layers in which the hole 304h is formed may be different. In some embodiments, different thin film transistors may include semiconductor layers with different materials, but not limited thereto.

In some embodiments, the circuit layer 304 may further include a buffer layer 346 disposed between the switch element 318 and the substrate 102. The buffer layer 346 may for example be used to block moisture or oxygen from entering the electronic device 31. The buffer layer 346 may for example include silicon nitride, silicon oxide, silicon oxynitride, aluminum oxide, resin, other suitable materials or the combinations of the above-mentioned materials, but not limited thereto. In the embodiments shown in FIG. 3A, the buffer layer 346 may not cover the optical sensor 110, but the present disclosure is not limited thereto.

As shown in FIG. 3A, in some embodiments, when the electronic device 31 is a self-luminous display device, the electronic device 31 may further include a light emitting element 334 for generating a light, and the optical sensor 110 may receive a portion of the light emitted from the light emitting element 334 through the light guiding channel 306A. The light emitting element 334 may for example be disposed on the planarization layer 306. In some embodiments, the planarization 306 may include a through hole 306v, such that the light emitting element 334 may be electrically connected to the switch element 318 through the through hole 306v. For example, the light emitting element 334 may include an electrode 336, a light emitting layer 338 and an electrode 340 stacked on the planarization layer 306 in sequence, and the electrode 336 may be electrically connected to one of the source/drains SD1 through the through hole 306v. The light emitting layer 338 may for example include organic light emitting materials, but not limited thereto. In some embodiments, the electronic device 31 may further include a pixel defining layer 342, and the pixel defining layer 342 may include an opening 342a, such that the opening 342a may define the region of a sub pixel or a pixel, but not limited thereto. In some embodiments, the light emitting layer 338 of the light emitting element 334 may for example be disposed in the opening 342a, such that the light emitting element 334 may be served as the sub pixel or the pixel of the display device, but not limited thereto. In some embodiments, when the electronic device 31 includes a plurality of light emitting elements 334, the light guiding channel 306A and the optical sensor 110 may be disposed adjacent to at least one of the light emitting elements 334, but not limited thereto. The pixel defining layer 342 may for example include organic material or other suitable materials, but not limited thereto. The organic material may for example include acrylic-based material, silicon-based material, epoxy-based material, other suitable organic materials or the combinations of the above-mentioned materials, but not limited thereto. The acrylic-based material may for example be poly(methyl methacrylate), polyimide, other suitable materials or the combinations of the above-mentioned materials, but not limited thereto.

In some embodiments, the light emitting element 334 may include light emitting diode (LED), micro light emitting diode (mini LED or micro LED), quantum dot material (QD), quantum dot light emitting diode (QLED, QDLED), nano wire light emitting diode, bar type light emitting diode, fluorescence material, phosphor material, other suitable materials or the combinations of the above-mentioned materials, but not limited thereto. In some embodiments, when the electronic device 31 is a self-luminous display device, the electronic device 31 may further include a protection layer 344 disposed on the light emitting element 334 and the pixel defining layer 342. For example, the protection layer 344 may include the stack of an inorganic material layer 344a, an organic material layer 344b and an inorganic material layer 344c to reduce the penetration of moisture or oxygen. The inorganic material layer 344a or the inorganic material layer 344c may for example include silicon nitride, silicon oxide, silicon oxynitride, aluminum oxide, other suitable protecting materials or the combinations of the above-mentioned inorganic materials, but not limited thereto. The inorganic material layer 344a and the inorganic material layer 344c may include the same material or different materials. The organic material layer 344b may include resin, but not limited thereto. In some embodiments, the protection layer 344 may also be a single inorganic material layer 344a or a stack of the plurality of inorganic material layers 344a.

In some embodiments, when the electronic device 31 is a non-self-luminous display device, the electronic device 31 may for example include liquid crystal layer, color filter, fluorescent material, phosphor material, other suitable materials or the combinations of the above-mentioned materials, but not limited thereto.

Referring to FIG. 3B, FIG. 3B schematically illustrates a cross-sectional view of an electronic device according to a variant embodiment of the third embodiment of the present disclosure. The difference between the electronic device 32 of the present variant embodiment and the electronic device 31 shown in FIG. 3A is that the planarization layer 306 may include a hole 306h, and the pixel defining layer 342 disposed on the planarization layer 306 may be disposed in the hole 306h. The hole 306h may at least partially overlap the hole 304h in the normal direction VD of the substrate 102. In the embodiment shown in FIG. 3B, the hole 306h may be smaller than the hole 304h, and accordingly, the hole 306h may be completely located in the hole 304h, but not limited thereto. In some embodiments, when the refractive index of the pixel defining layer 342 is greater than the refractive index of the planarization layer 306, the pixel defining layer 342 may also include the light guiding channel 342A disposed in the hole 306h and surrounded by the planarization layer 306 and the film portion 342B located on the planarization layer 306, such that another interface 348 may be formed between the pixel defining layer 342 in the hole 306h and the planarization layer 306, and the light guiding channel 342A is thereby formed. Accordingly, the light guiding channel 342A is formed by being surrounded by the interface 348. In the embodiment shown in FIG. 3B, the interface 348 may be located at the sidewall of the hole 306h, and the light in the light guiding channel 342A may be totally reflected at the interface 348. In addition, when the refractive index of the planarization layer 306 is greater than the refractive index of the insulating layer 322, the refractive index of the insulating layer 326 and the refractive index of the insulating layer 330, the interface 312 may reflect the portion of the light which passes through the interface 348 (that is, the light which is not totally reflected at the interface 348), and therefore, the intensity of the light may be further improved through the light guiding channel 306A of the planarization layer 306 located between the interface 312 and the interface 348. Since the refractive indices of the films located in the hole 304h may be sequentially reduced from the center of the hole 304h to the sidewall of the hole 304h, the loss during the transmission of the light in the hole 304h may be reduced to improve the intensity of the light transmitted to the optical sensor 110. For example, the materials of the pixel defining layer 342 and the planarization layer 306 may be selected from different materials under the condition that the refractive index of the pixel defining layer 342 is greater than the refractive index of the planarization layer 306. The refractive index of the pixel defining layer 342 for the light having a wavelength of 550 nanometers may for example greater than or equal to 1.5 and lower than or equal to 3.0, but not limited thereto. In some embodiments, the hole 306h may be a through hole or a blind hole of the planarization layer 306.

In the embodiment shown in FIG. 3B, the light guiding channel 306A and the light guiding channel 342A may overlap the optical sensor 110 in the normal direction VD of the substrate 102. For example, the maximum width W1 of the optical sensor 110 in the direction perpendicular to the normal direction VD may be greater than or equal to the maximum width W2 of the bottom of the hole 304h in the direction perpendicular to the normal direction VD. In some embodiments, the light guiding channel 342A may overlap the optical sensor 110 in the normal direction VD. In some embodiments, the hole 304h may at least partially overlap the optical sensor 110 in the normal direction VD. For example, the maximum width W1 of the optical sensor 110 in the direction perpendicular to the normal direction VD may be greater than or equal to the maximum width W2 of the bottom of the hole 304h in the direction perpendicular to the normal direction VD, and may be greater than the maximum width W3 of the hole 306h in the direction perpendicular to the normal direction VD, but not limited thereto. In some embodiments, the maximum width W1 of the optical sensor 110 in the direction perpendicular to the normal direction VD may be less than the maximum width W2 of the bottom of the hole 304h in the direction perpendicular to the normal direction VD and may be greater than or equal to the maximum width W3 (not shown) of the hole 306h in the direction perpendicular to the normal direction VD, but not limited thereto.

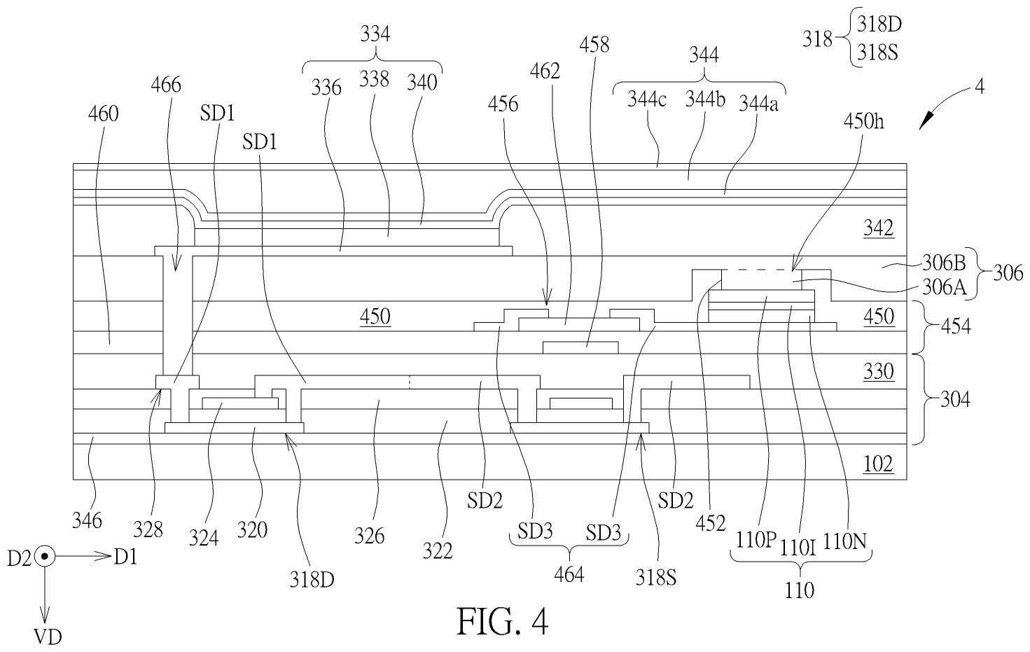

Referring to FIG. 4, FIG. 4 schematically illustrates a cross-sectional view of an electronic device according to a fourth embodiment of the present disclosure. In the electronic device 4 of the present embodiment, the optical sensor 110 may be disposed on the circuit layer 304. In the embodiment shown in FIG. 4, the optical sensor 110 may be disposed between the circuit layer 304 and the planarization layer 306, and the electronic device 4 may further include an insulating layer 450 disposed between the optical sensor 110 and the planarization layer 306. The refractive index of the insulating layer 450 may be less than the refractive index of the planarization layer 306, the insulating layer 450 may include a hole 450h located on the optical sensor 110, and a portion of the planarization layer 306 may be disposed in the hole 450h, such that the insulating layer 450 and the planarization layer 306 in the hole 450h may form an interface 452 on the optical sensor 110, and a light guiding channel 306A is thereby formed. The light guiding channel 306A is surrounded by the interface 452. In some embodiments, the hole 450h may be the through hole of the insulating layer 450, such that the light guiding channel 306A may directly be in contact with the optical sensor 110. In some embodiments, the hole 450h may also be the blind hole of the insulating layer 450. In some embodiments, the insulating layer 450 may for example be similar to or the same as the layer 216 of the second layer 106 shown in FIG. 2A or FIG. 2B, or, the insulating layer 450 may further include the reflector 214 shown in FIG. 2A or FIG. 2B.

In the embodiment shown in FIG. 4, the maximum width of the optical sensor 110 in the direction perpendicular to the normal direction VD may be greater than or equal to the maximum width of the bottom of the hole 450h in the direction perpendicular to the normal direction VD. In some embodiments, the planarization layer 306 may also include hole (not shown in FIG. 4, such as the hole 306h shown in FIG. 3B), and a portion of the pixel defining layer 342 is disposed in the hole of the planarization layer 306. Accordingly, the electronic device 4 may include a plurality of light guiding channels (such as the light guiding channel 306A and the light guiding channel 342A) formed by a plurality of interfaces, but not limited thereto. In some embodiments, under the condition that the planarization layer 306 includes the hole (such as the hole 306h shown in FIG. 3B), and a portion of the pixel defining layer 342 is disposed in the hole of the planarization layer 306, the maximum width of the optical sensor 110 in the direction perpendicular to the normal direction VD may be greater than or equal to the maximum width of the bottom of the hole 450h in the direction perpendicular to the normal direction VD and may be greater than the maximum width of the hole of the planarization layer 306 in the direction perpendicular to the normal direction VD. In some embodiments, the maximum width of the optical sensor 110 in the direction perpendicular to the normal direction VD may be less than the maximum width of the bottom of the hole 450h in the direction perpendicular to the normal direction VD and may be greater than the maximum width (not shown in FIG. 4) of the hole 306h in the direction perpendicular to the normal direction VD, but not limited thereto.

In some embodiments, the optical sensor 110 may include photodiodes, and may for example include a P type semiconductor layer 110P, an intrinsic semiconductor layer 1101 and a N type semiconductor layer 110N stacked on the circuit layer 304 in sequence, but not limited thereto. In some embodiments, the stacking order of the P type semiconductor layer 110P, the intrinsic semiconductor layer 1101 and the N type semiconductor layer 110N on the circuit layer 304 may also be changed. Because the optical sensor 110 includes a multi-layer structure, the width of the optical sensor 110 in the direction perpendicular to the normal direction VD may be decided by the width of the P type semiconductor layer 110P, the intrinsic semiconductor layer 1101 and the N type semiconductor layer 110N in the direction perpendicular to the normal direction VD. In other words, the minimum width in the width of the P type semiconductor layer 110P, the width of the intrinsic semiconductor layer 1101 and the width of the N type semiconductor layer 110N is regarded as the width of the optical sensor 110.

In some embodiments, the electronic device 4 may further include a circuit layer 454 electrically connected to the optical sensor 110 and disposed on the circuit layer 304. For example, the optical sensor 110 is disposed in the circuit layer 454, and the insulating layer 450 may be included in the circuit layer 454. The circuit layer 454 may include a switch element 456 disposed between the insulating layer 450 and the circuit layer 304. For example, the switch element 456 may include thin film transistor or other suitable transistors, but not limited thereto. In some embodiments, when the thin film transistor in the circuit layer 454 is a bottom-gate type transistor, the circuit layer 454 may include a conductive layer 458, an insulating layer 460, a semiconductor layer 462 and a conductive layer 464, wherein the conductive layer 458 is disposed on the insulating layer 330 and may include the gate of the thin film transistor; the insulating layer 460 is disposed between the conductive layer 458 and the insulating layer 450 and may be served as the gate insulating layer of the thin film transistor; the semiconductor layer 462 is disposed between the insulating layer 460 and the insulating layer 450 and may include the channel layer of the thin film transistor; and the conductive layer 464 is disposed between the semiconductor layer 462 and the insulating layer 450 and may include the source/drains SD3 of the thin film transistor, and one of the source/drains SD3 may be electrically connected to the P type semiconductor layer 110P or the N type semiconductor layer 110N of the optical sensor 110.

The disposition relationship of the gate, the gate insulating layer, the channel layer, and source/drains SD3 of the thin film transistor in the circuit layer 454 of the present disclosure is not limited to the above-mentioned contents, and the disposition relationship may be different according to the types of the thin film transistor. In some embodiments, the thin film transistor in the circuit layer 454 may for example be a top-gate type transistor, or may be changed to a double-gate transistor or other suitable transistors according to the demands. Or, the thin film transistor may also include amorphous silicon transistor, low-temperature poly-silicon transistor or metal-oxide semiconductor transistor, but not limited thereto. In some embodiments, different thin film transistors in the circuit layer 454 may include semiconductor layers with different materials, but not limited thereto.

In the embodiment shown in FIG. 4, the circuit layer 304 may include a plurality of switch elements 318, and the switch element 456 in the circuit layer 454 may overlap at least one switch element 318 in the normal direction VD of the substrate 102. For example, when the electronic device 4 is a self-luminous display device, the switch elements 318 in the circuit layer 304 may include a switching element 318S and a driving element 318D, the light emitting element 334 may be electrically connected to one of the source/drains SD1 of the driving element 318D through the through hole 466 of the planarization layer 306, the insulating layer 450, the insulating layer 460 and the insulating layer 330, and another one of the source/drains SD1 of the driving element 318D may be electrically connected to the gate of the driving element 318D and one of the source/drains SD2 of the switching element 318S. In some embodiments, one of the source/drains SD2 of the switching element 318S and one of the source/drains SD1 of the driving element 318D may share the same electrode, but not limited thereto.

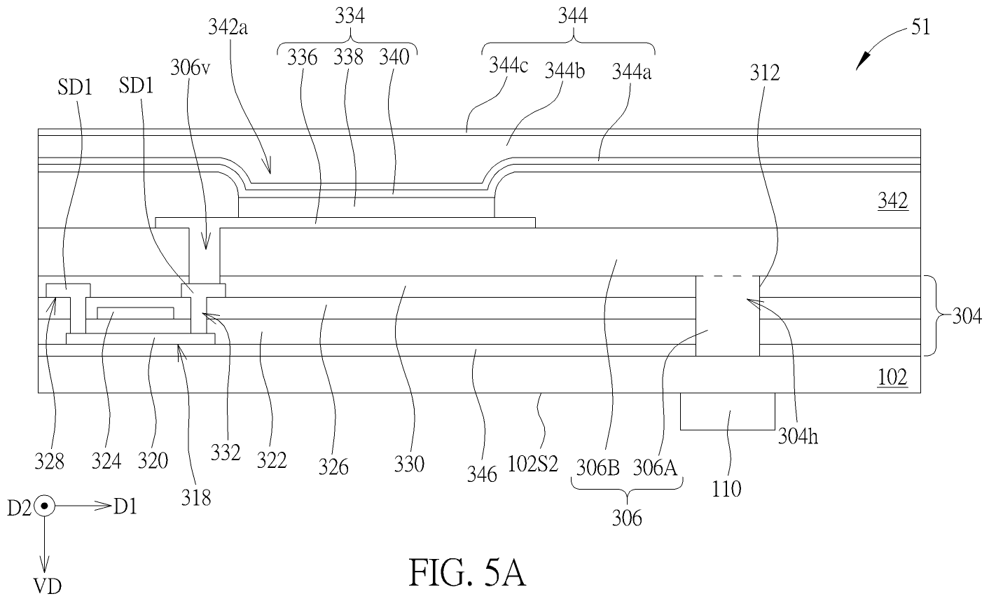

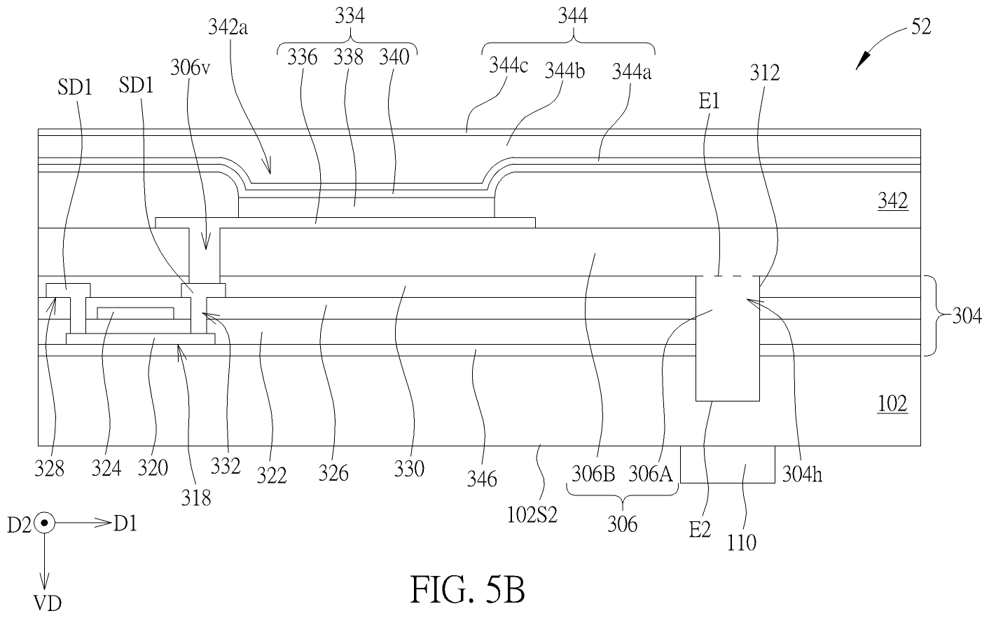

Referring to FIG. 5A, FIG. 5A schematically illustrates a cross-sectional view of an electronic device according to a fifth embodiment of the present disclosure. In the electronic device 51 of the present embodiment, the optical sensor 110 may be disposed on a bottom surface 102S2 of the substrate 102 opposite to the circuit layer 304. In the embodiment shown in FIG. 5A, the hole 304h may be formed of the through hole of the insulating layer 330, the insulating layer 326, the insulating layer 322 and the buffer layer 346, such that the planarization layer 306 may be in contact with the substrate 102, but not limited thereto. In some embodiments, the hole 304h may not extend into the substrate 102. In some embodiments, the hole 304h may be formed of the through hole of the insulating layer 330, the insulating layer 326 and the insulating layer 322 and a blind hole of the buffer layer 346. In some embodiments, the hole 304h may be formed of the through hole of the insulating layer 330 and the insulating layer 326 and a through hole or a blind hole of the insulating layer 322. In some embodiments, the hole 304h may be formed of the through hole of the insulating layer 330 and a through hole or a blind hole of the insulating layer 326. In some embodiments, the hole 304h may be a through hole or a blind hole of the insulating layer 330, but not limited thereto. The other elements and disposition relationship in the electronic device 51 may be the same as or similar to the electronic device 31 shown in FIG. 3A, and will not be redundantly described herein.

Referring to FIG. 5B, FIG. 5B schematically illustrates a cross-sectional view of an electronic device according to a variant embodiment of the fifth embodiment of the present disclosure. The difference between the electronic device 52 of the present variant embodiment and the electronic device 51 shown in FIG. 5A is that the hole 304h may extend into the substrate 102, such that the edge E2 of the light guiding channel 306A may be closer to the optical sensor 110, thereby increasing the intensity of the light received by the optical sensor 110. In the embodiment shown in FIG. 5B, the substrate 102 may be a single-layer structure, and the hole 304h may be formed of the through hole of the insulating layer 330, the insulating layer 326, the insulating layer 322 and the buffer layer 346 and a blind hole of the substrate 102, but not limited thereto.

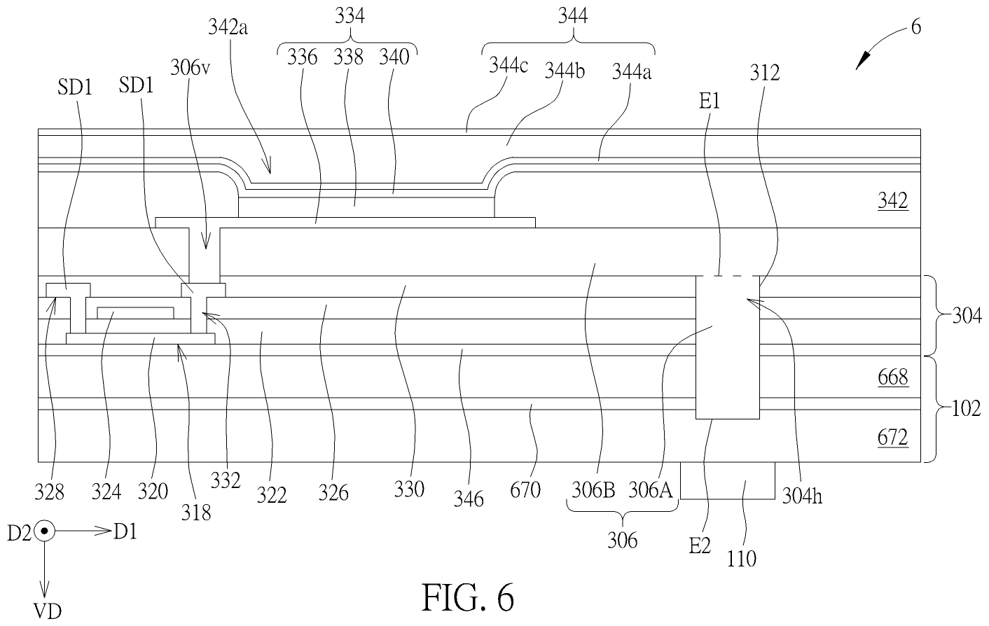

Referring to FIG. 6, FIG. 6 schematically illustrates a cross-sectional view of an electronic device according to a sixth embodiment of the present disclosure. In the electronic device 6 of the present embodiment, the substrate 102 may include a multi-layer structure. In the embodiment shown in FIG. 6, the substrate 102 may include a second substrate 672, an intermediate layer 670 and a first substrate 668 stacked in sequence, and the circuit layer 304 is disposed on the first substrate 668, but not limited thereto. The first substrate 668 and the second substrate 672 may for example include rigid substrate or flexible substrate. The material of the rigid substrate and the material of the flexible substrate may refer to the above-mentioned contents, and will not be redundantly described here. The intermediate layer 670 may for example include the materials used to block the moisture or gas (such as oxygen), such as silicon oxide, silicon oxynitride, aluminum oxide, aluminum oxynitride, other suitable materials or the combinations of the above-mentioned materials, but not limited thereto.

In some embodiments, the hole 304h may further include the through hole of the first substrate 668 and the intermediate layer 670 and a blind hole of the second substrate 672 besides the through hole of the insulating layer 330, the insulating layer 326, the insulating layer 322 and the buffer layer 346. Accordingly, the distance between the hole 304h and the optical sensor 110 may be shortened, such that the edge E2 of the light guiding channel 306A may be closer to the optical sensor 110, thereby increasing the intensity of the light received by the optical sensor 110. In some embodiments, the hole 304h may not extend into the second substrate 672, and may be formed of the through hole of the insulating layer 330, the insulating layer 326, the insulating layer 322, the buffer layer 346 and the first substrate 668 and a through hole or a blind hole of the intermediate layer 670. In some embodiments, the hole 304h may not extend into the intermediate layer 670, and may be formed of the through hole of the insulating layer 330, the insulating layer 326, the insulating layer 322 and the buffer layer 346 and a through hole or a blind hole of the first substrate 668, but not limited thereto.

In summary, in the electronic device of the present disclosure, the intensity of the light received by the optical sensor may be increased by disposing a light guiding channel on the optical sensor. Accordingly, when the optical sensor is used to detect the light reflected by an object, such as the light reflected by the fingerprint, the sharpness of the detected images may be improved due to the design of the light guiding channel.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device comprising:
a substrate;
a first layer disposed on the substrate; and
a second layer disposed on the substrate and surrounding the first layer,
wherein an interface between the first layer and the second layer forms a light guiding channel.

2. The electronic device of claim 1, wherein a refractive index of the first layer is greater than a refractive index of the second layer.

3. The electronic device of claim 1, wherein the second layer comprises a reflector.

4. The electronic device of claim 3, wherein the reflector comprises metal.

5. The electronic device of claim 3, wherein the reflector comprises multiple layers having at least two different refractive indices.

6. The electronic device of claim 1, wherein the second layer is a multi-layer structure.

7. The electronic device of claim 6, further comprising a thin film transistor embedded in the second layer.

8. The electronic device of claim 1, further comprising:
a light emitting element for emitting a light; and
an optical sensor for receiving a portion of the light through the light guiding channel.
